(19) United States
(12) Patent Application Publication
(10) Pub. No.: US 2017/0352795 A1
(43) Pub. Date: Dec. 7, 2017

(54) SENSOR AND/OR TRANSDUCER DEVICE AND METHOD FOR OPERATING A SENSOR AND/OR TRANSDUCER DEVICE HAVING AT LEAST ONE BENDING STRUCTURE, WHICH INCLUDES AT LEAST ONE PIEZOELECTRIC LAYER

(71) Applicant: Robert Bosch GmbH, Stuttgart (DE)

(72) Inventors: Fabian Purkl, Rutesheim (DE); Kerrin Doessel, Stuttgart (DE); Thomas Buck, Tamm (DE)

(21) Appl. No.: 15/594,913

(22) Filed: May 15, 2017

(30) Foreign Application Priority Data
Jun. 7, 2016 (DE) 102016210008.4

(51) Int. Cl. H01L 41/00; G01H 11/08; H04R 17/02

(52) U.S. Cl. CPC H01L 41/00; H04R 17/02; G01H 11/08; H04R 2410/03

(57) ABSTRACT

A sensor and/or transducer device having at least one bending structure including at least one piezoelectric layer in each case, using which an intermediate volume between at least two electrodes of the bending structure is at least partially filled in each case, the sensor and/or transducer device including an electronic unit, which is designed to apply at least one predefined or established actuator voltage between two of the electrodes at a time of the bending structure in such a way that a deformation of the bending structure triggered by an intrinsic stress gradient in the bending structure may be at least partially compensated for. A method for operating a sensor and/or transducer device having at least one bending structure, which includes at least one piezoelectric layer, and a method for calibrating a microphone having at least one bending structure, which includes at least one piezoelectric layer, are also described.

### CROSS REFERENCE

The present application claims the benefit under 35 U.S.C. §119 of German Patent Application No. DE 102016210008.4 filed on Jun. 7, 2016, which is expressly incorporated herein by reference in its entirety.

### FIELD

The present invention relates to a sensor and/or transducer device, in particular a microphone. The present invention also relates to a method for operating a sensor and/or transducer device having at least one bending structure, which includes at least one piezoelectric layer. Furthermore, the present invention relates to a method for calibrating a microphone having at least one bending structure, which includes at least one piezoelectric layer.

### BACKGROUND INFORMATION

Sensor and/or transducer devices, which have at least one bending structure, which includes at least one piezoelectric layer, are conventional. The particular bending structure has at least one self-supporting area, which is adjustable, under a compression and/or elongation of the at least one piezoelectric layer, in relation to an anchored area of the bending structure.

For example, U.S. Patent Appl. Pub. No. 2014/0339657 A1 describes a piezoelectric microphone which has a plurality of such bending structures.

### SUMMARY

The present invention provides a sensor and/or transducer device, a microphone, a method for operating a sensor and/or transducer device having at least one bending structure, which includes at least one piezoelectric layer, and a method for calibrating a microphone having at least one bending structure, which includes at least one piezoelectric layer.

The present invention may provide cost-effective and easily implementable possibilities for at least partially compensating for a deformation, which is triggered by the intrinsic stress gradient in the particular bending structure and is generally undesirable, of the at least one bending structure of the particular sensor and/or transducer device. A gap/air gap, which is typically to be accepted as a result of the deformation caused by the intrinsic stress gradient, and which influences a sensitivity of the particular bending structure (or the sensor and/or transducer device equipped therewith) may therefore easily be reduced in size/closed with the aid of the present invention. The present invention therefore contributes to improving the sensitivity of sensor and transducer devices having at least one bending structure, which includes at least one piezoelectric layer.

The intrinsic stress gradient occurring in the bending structure may also be interpreted as a differing mechanical stress (or a differing mechanical tension/a differing intrinsic tension/a differing intrinsic stress) with respect to multiple (piezoelectric and/or non-piezoelectric) layers contacting one another. The intrinsic stress occurring, for example, in the at least one piezoelectric layer of the at least one bending structure of a sensor and/or transducer device may result in particular from the deposition process for producing the at least one piezoelectric layer. Since the consequences of the intrinsic stress are at least reducible with the aid of the present invention, the present invention enables the use of cost-effective and easily/rapidly executable deposition methods for producing the at least one piezoelectric layer (or at least one non-piezoelectric layer), without disadvantages having to be accepted thereafter during operation of the particular sensor and/or transducer device as a result of the intrinsic stress resulting from the deposition method used. The present invention therefore also contributes to reducing the manufacturing costs for sensor and/or transducer devices and improving and/or accelerating a manufacturability of sensor and/or transducer devices.

In one advantageous specific embodiment of the sensor and/or transducer device, the bending structure includes, as electrodes, at least one first outer electrode, at least one second outer electrode, and at least one intermediate electrode, which is situated between the at least one first outer electrode and the at least one second outer electrode, and a first piezoelectric layer, which is provided in a first intermediate volume between the at least one first outer electrode and the at least one intermediate electrode, and a second piezoelectric layer, which is provided in a second intermediate volume between the at least one intermediate electrode and the at least one second outer electrode, as the at least one piezoelectric layer. The present invention is therefore also applicable for a layer construction for the at least one bending structure, which is advantageously suitable for detecting an action of a force or a pressure (in particular a soundwave) on the at least one bending structure: In a bending structure having the layer construction described here, in the event of a deformation of the bending structure, a tensile stress occurs in one of the two piezoelectric layers and a compression stress occurs in the other of the two piezoelectric layers. The deformation of the bending structure may therefore be reliably ascertained/demonstrated on the basis of a voltage signal tapped at one of the two piezoelectric layers.

For example, the bending structure may include, as electrodes, only the first outer electrode, the second outer electrode, and the intermediate electrode situated between the first outer electrode and the second outer electrode, the electronic unit being able to be designed to output at least one electric output signal with respect to a sensing voltage applied between the first outer electrode and the intermediate electrode and to apply the predefined or established actuator voltage between the intermediate electrode and the second outer electrode. This specific embodiment of the sensor and/or transducer device therefore requires (despite the advantageous compensation ability of the deformation triggered by the particular intrinsic stress gradient in the bending structure) only three electrodes per bending structure. In one alternative specific embodiment, at least two of the electrodes may also be used both for balancing the sensing voltage applied between them and for applying the particular actuator voltage between them at the same time. In this case, the particular actuator voltage (as a DC voltage signal) may be filtered out of the sensing voltage (as an AC voltage signal) with the aid of a cost-effective filter (for example, a low-pass filter).

In another advantageous specific embodiment of the sensor and/or transducer device, the bending structure includes a first sensing electrode and a first actuator electrode as the at least one first outer electrode, a second sensing electrode and a second actuator electrode as the at least one second outer electrode, and a third sensing electrode, which is located between the first sensing electrode and the second sensing electrode, and a third actuator electrode, which is located between the first actuator electrode and the second actuator electrode, as the at least one intermediate electrode. In this case, the electronic unit is preferably designed to output at least one electrical output signal with respect to at least one sensing voltage applied between two of the sensing electrodes at a time and to apply the at least one predefined or established actuator voltage between two of the actuator electrodes at a time. Sensing and actuation may therefore be clearly separated.

In one advantageous refinement, the sensor and/or transducer device has at least two bending structures, which each include the at least one piezoelectric layer, and the electronic unit is designed to apply different predefined or established actuator voltages between the electrodes of the various bending structures. With the aid of the present invention, it is therefore also possible to react to the fact that the occurring intrinsic stress gradient may vary (randomly) between the various bending structures. Nonetheless, it may be ensured with the aid of the present invention that each of the at least two bending structures has a form optimized for operation/sensitivity of the sensor and/or transducer device.

The above-described advantages are also ensured in a microphone having such a sensor and/or transducer device.

In one advantageous specific embodiment of the microphone, the electronic unit is additionally designed to establish a minimum limiting value of a frequency range of sound waves which may be amplified with the aid of the microphone, by applying the at least one predefined or established actuator voltage between two of the electrodes at a time of the bending structure with the aid of the electronic unit in such a way that the deformation of the bending structure triggered by the intrinsic stress gradient is at least partially compensated for or increased. As explained in greater detail hereafter, the minimum limiting value of the frequency range of sound waves which may be amplified may be adapted in particular to surroundings conditions.

Carrying out the corresponding method for operating a sensor and/or transducer device having at least one bending structure, which includes at least one piezoelectric layer, also causes the above-described advantages. It is to be noted that the method is refinable according to the above-described specific embodiments of the sensor and/or transducer device.

Furthermore, carrying out the corresponding method for calibrating a microphone having at least one bending structure, which includes at least one piezoelectric layer, also yields the above-mentioned advantages. The method for calibrating a microphone having at least one bending structure, which includes at least one piezoelectric layer, is accordingly also refinable according to the above-described specific embodiments of the sensor and/or transducer device.

### BRIEF DESCRIPTION OF THE DRAWINGS

Further features and advantages of the present invention are explained below on the basis of the figures.

FIGS. 1a through 1d show schematic views and a circuit of a first specific embodiment of the sensor and/or transducer device.

FIGS. 2a and 2b show schematic views of a second specific embodiment of the sensor and/or transducer device.

FIG. 3 shows a flow chart to explain a method for operating a sensor and/or transducer device having at least one bending structure, which includes at least one piezoelectric layer.

### DETAILED DESCRIPTION OF EXAMPLE EMBODIMENTS

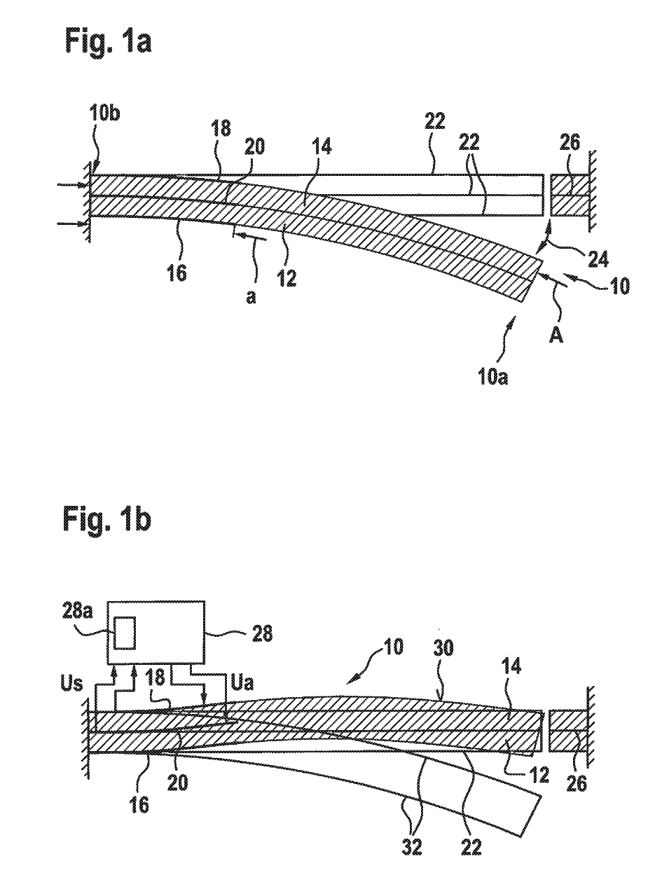

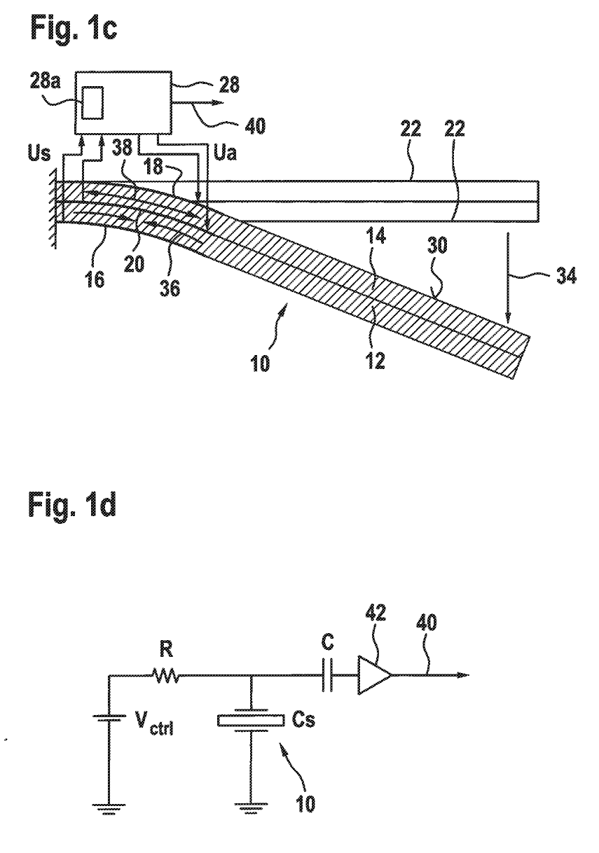

FIGS. 1a through 1d show schematic views and a circuit of a first specific embodiment of the sensor and/or transducer device.

The sensor and/or transducer device which is schematically shown with the aid of FIGS. 1a through 1d may also be referred to as a sound sensor device and/or sound transducer device. The sensor and/or transducer device is designed as a microphone, for example. However, it is to be noted that the implementability of the sensor and/or transducer device described hereafter is not limited to microphones. For example, the sensor and/or transducer device may also be used for a variety of inertial sensor devices.

The sensor and/or transducer device of FIGS. 1a through 1d has a (single) bending structure 10. Alternatively, however, the sensor and/or transducer device may also have multiple bending structures 10, in particular a plurality of bending structures 10, each having the corresponding features. Bending structure 10 includes at least one piezoelectric layer 12 and 14, single piezoelectric layer or each of piezoelectric layers 12 and 14 each at least partially filling up an intermediate volume between at least two electrodes 16 through 20 of bending structure 10. Bending structure 10 may be designed, for example, as a diaphragm, in particular as a diaphragm equipped with slots and/or holes. Bending structure 10 may also be understood as a bending bar structure, for example, a bar-shaped and/or web-shaped bending bar structure. It is to be noted that bending structure 10 may also have a variety of other forms.

In the specific embodiment of FIGS. 1a through 1d, bending structure 10 has, as electrodes 16 through 20, a first outer electrode 16, a second outer electrode 18, and an intermediate electrode 20, which is situated/located between first outer electrode 16 and second outer electrode 18. A first intermediate volume between first outer electrode 16 and intermediate electrode 20 is at least partially (in particular completely) filled using a first piezoelectric layer 12. Accordingly, a second intermediate volume between intermediate electrode 20 and second outer electrode 18 is at least partially (in particular completely) filled using a second piezoelectric layer 14. By way of example, first piezoelectric layer 12 is deposited directly on first outer electrode 16 and intermediate electrode 20 is formed directly on a surface of first piezoelectric layer 12 directed away from first outer electrode 16, while second piezoelectric layer 14 is deposited directly on intermediate electrode 20 and second outer electrode 18 is formed directly on a surface of second piezoelectric layer 14 directed away from intermediate electrode 20. However, it is to be noted that an implementability of bending structure 10 is not limited to the layer construction shown in FIGS. 1a through 1c. For example, in addition to first piezoelectric layer 12 and/or second piezoelectric layer 14, at least one further intermediate layer may also be located between first outer electrode 16 and intermediate electrode 20 and/or intermediate electrode 20 and second outer electrode 18.

Electrodes 16 through 20 may (perpendicularly in relation to a direction from first outer electrode 16 to second outer electrode 18) have an extension a, which is significantly less than an extension A of the at least one piezoelectric layer 12 and 14 (perpendicularly in relation to a direction from first outer electrode 16 to second outer electrode 18). For example, an extension a of electrodes 16 through 20 is approximately one-third of extension A of piezoelectric layers 12 and 14. Notwithstanding the depiction in FIGS. 1a through 1c, electrodes 16 through 20 may also have different extensions a and/or piezoelectric layers 12 and 14 may have extensions A which differ from one another.

Instead of the design of bending structure 10 having two piezoelectric layers 12 and 14, as shown in FIGS. 1a through 1c, however, instead of one of piezoelectric layers 12 and 14, a non-piezoelectric layer may be situated. One of outer electrodes 16 or 18 may optionally be saved in this case.

Bending structure 10 has at least one self-supporting area 10a/at least one self-supporting end, which is adjustable under a compression and/or elongation of the at least one piezoelectric layer 12 and 14 in relation to an anchored area 10b/anchored end of bending structure 10. Bending structure 10 is therefore deformable with the aid of a force exerted thereon and/or a pressure exerted thereon, the at least one piezoelectric layer 12 and 14 being compressed and/or elongated. Since a variety of options are possible for fixing anchored area 10b/anchored end, this will not be discussed in greater detail here.

Before a release of the at least one self-supporting area 10a/self-supporting end of bending structure 10 (in general by removing a sacrificial layer material), bending structure 10 is provided in an initial position, which is shown with the aid of lines 22 in FIG. 1a. During a formation of bending structure 10 using at least one deposition method (for example, for depositing the at least one piezoelectric layer 12 and 14), however, an intrinsic stress gradient is frequently formed, which, after the release of the at least one self-supporting area 10a/self-supporting end of bending structure 10, results in a deformation of bending structure 10 out of the initial position. The deformation of bending structure 10 triggered by the intrinsic stress gradient in bending structure 10 results in the example of FIG. 1a in an opening/an enlargement of a gap/air gap 24 between self-supporting area 10a of bending structure 10, which is directed away from anchored area 10b, and a structure 26 adjacent thereto. (Adjacent structure 26 may be formed, for example, from the material of the at least one piezoelectric layer 12 and 14.) Gap 24 may be in particular in an order of magnitude of several tens of micrometers (10 μm). A gap size of gap 24 may also vary significantly as a result of scattering.

The deformation of bending structure 10 triggered by the intrinsic stress gradient (in bending structure 10) may typically impair a sensitivity of the sensor and/or transducer device. In a sensor and/or transducer device used as a microphone, gap 24 frequently causes a variable “leak resistance,” which makes it impossible to amplify low sound frequencies.

However, the sensor and/or transducer device has a (schematically shown) electronic unit 28, which is designed to apply at least one actuator voltage Ua between two of electrodes 16 through 20 at a time of bending structure 10 in such a way that the deformation of bending structure 10 triggered by the intrinsic stress gradient may be at least partially compensated for (see FIG. 1b). Gap 24 shown in FIG. 1a may therefore be reduced in size/closed with the aid of electronic unit 28.

Typical effects of intermediate gap 24 on a sensitivity of bending structure 10/the sensor and/or transducer device equipped therewith therefore no longer have to be accepted due to the equipping of the sensor and/or transducer device with electronic unit 28. Equipping the sensor and/or transducer device with advantageously designed electronic unit 28 therefore contributes to improving the sensitivity of bending structure 10/the sensor and/or transducer device equipped therewith.

FIG. 1b shows a form of bending structure 10 in which no sound wave is incident on a receiving surface 30 of bending structure 10. The deformation of bending structure 10 which may be caused by the intrinsic stress gradient is shown in FIG. 1b with the aid of lines 32. The at least one actuator voltage Ua, which is applied with the aid of electronic unit 28 between electrodes 16 through 20, causes “bending back” of bending structure 10 in this situation, in adaptation to its initial position (before the release of the at least one self-supporting area 10a/self-supporting end). Voltage Ua may be overlaid on the sensing voltage as a DC voltage, as shown in FIG. 1d as an electronic circuit. FIG. 1c shows a configuration of circuit 28 alternative thereto, in which the actuator voltage does not act on the same electrode pair as the sensing, which enables a simplified electronic circuit.

The at least one actuator voltage Ua may be at least one (permanently) predefined actuator voltage Ua or at least one (newly) established actuator voltage Ua. For example, the at least one (permanently) predefined actuator voltage Ua may be stored unerasably on a (nonerasable) memory 28a. During a startup of the sensor and/or transducer device, memory 28a may be read out automatically and the at least one actuator voltage Ua may subsequently be applied accordingly. Alternatively, the sensor and/or transducer device may also be designed to (regularly) carry out a self-calibration to predetermine/newly predetermine the at least one actuator voltage Ua and possibly to buffer the at least one actuator voltage Ua subsequently on (erasable) memory 28a. Advantageous possibilities for establishing/reestablishing the at least one actuator voltage Ua are also described hereafter. The present invention therefore provides extremely sensitive sensor and/or transducer devices.

It is also to be noted that to manufacture the sensor and/or transducer device described here, only comparatively few requirements are to be maintained by the at least one deposition method carried out to form bending structure 10. Since the intrinsic stress gradient which results in bending structure 10 during the particular deposition method which is carried out, or the effects thereof on bending structure 10, may be easily compensated for, a variety of deposition methods which may be carried out simply and rapidly may be used (in particular to manufacture the at least one piezoelectric layer 12 and 14). In addition, it is not necessary to form at least one stabilizing intermediate layer on bending structure 10, to counteract an intrinsic stress gradient occurring in the at least one piezoelectric layer 12 and 14. This reduces the manufacturing costs of bending structure 10, or the sensor and/or transducer device equipped therewith.

FIG. 1c shows bending structure 10 during an incidence of a soundwave 34 on receiving surface 30. As is apparent, soundwave 34 causes a significant deformation of bending structure 10, which results, for example, in a compression stress 36 in first piezoelectric layer 12 and a tensile stress 38 in second piezoelectric layer 14. The deformation of bending structure 10 triggered by sound signal 34 may therefore be ascertained/demonstrated with the aid of at least one sensing voltage Us tapped between two of electrodes 16 through 20. Electronic unit 28 may therefore output a corresponding electrical output signal 40 with respect to the at least one sensing voltage Us, or with respect to soundwave 34. It is to be noted that the compensation of the intrinsic stress gradient caused by the at least one applied actuator voltage Ua does not impair or hardly impairs a reaction of bending structure 10 to the incidence of soundwave 34 on receiving surface 30.

As is apparent in FIG. 1c, sound signal 34 causes significant compressions/elongations of the at least one piezoelectric layer 12 and 14, in particular close to the at least one anchored area 10b/anchored end of bending structure 10. Electrodes 16 through 20 are therefore preferably located near to or directly on anchored area 10b/anchored end of bending structure 10.

Electronic unit 28 may also be designed in particular to establish a minimum limiting value of a frequency range of soundwave 34 which may be amplified (with the aid of the sensor and/or transducer device designed as a microphone), in that the at least one predefined or established actuator voltage Ua may be applied/is applied between two of electrodes 16 through 20 of bending structure 10 at a time with the aid of electronic unit 28, in such a way that the deformation of bending structure 10 triggered by the intrinsic stress gradient is at least partially compensated for or increased.

FIG. 1d shows an example of a possible circuit of electronic unit 28, in which actuator voltage Ua and sensing voltage Us are measured at the same electrode pair (see FIG. 1b). A voltage source (Vctrl in FIG. 1d) generates a DC voltage, which is applied via a high resistance to the sensing or actuator electrodes/actuation electrodes. The low-pass filter thus formed from R and the capacitance of the sensor/actuator Cs has a preferably low limiting frequency (<50 Hz), which is advantageously less than the lowest sensing frequency of the microphone/sensor. The output signal is separated by a capacitor C from actuator DC voltage component Ua at the electrodes and output 40 via an amplifier 42 having a low output impedance.

In the specific embodiment of FIG. 1c, electronic unit 28 is designed to apply predefined or established actuator voltage Ua between intermediate electrode 20 and second outer electrode 18 and to output the at least one electrical output signal 40 with respect to sensing voltage Us applied between first outer electrode 16 and intermediate electrode 20. Electronic unit 28 may also be designed to apply predefined or established actuator voltage Ua between first outer electrode 16 and intermediate electrode 20 and to output the at least one electrical output signal with respect to sensing voltage Us applied between intermediate electrode 20 and second outer electrode 18.

In another alternative specific embodiment, electronic unit 28 may also be designed to use at least two of electrodes 16 through 20 both for applying the at least one predefined or established actuator voltage Ua and for simultaneously tapping the at least one sensing voltage Us. If desired, in this case a filter may be used for filtering out the at least one actuator voltage Ua (as a DC voltage signal) from the at least one sensing voltage Us (as an AC voltage signal).

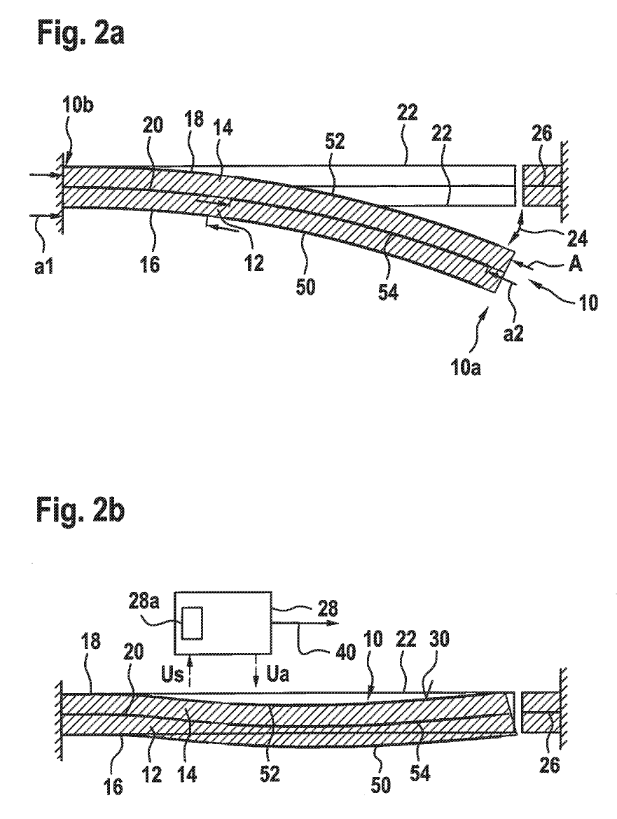

FIGS. 2a and 2b show schematic views of a second specific embodiment of the sensor and/or transducer device.

The sensor and/or transducer device which is schematically shown in FIGS. 2a and 2b has, as a supplement to the above-described specific embodiment, in addition to electrodes 16 through 20 (already described above) used as sensing electrodes 16 through 20, also a first actuator electrode 50, a second actuator electrode 52, and a third actuator electrode 54. First actuator electrode 50 is located together with first sensing electrode/first outer electrode 16 on a side/surface of first piezoelectric layer 12 directed away from second piezoelectric layer 14. Second actuator electrode 52 is situated together with second outer electrode/second sensing electrode 18 on a side/surface of second piezoelectric layer 14 directed away from first piezoelectric layer 12. Third actuator electrode 54 is located together with intermediate electrode/third sensing electrode 20 between piezoelectric layers 12 and 14.

As is apparent on the basis of a comparison of FIGS. 2a and 2b, electronic unit 28 is designed to apply the at least one predefined or established actuator voltage Ua between two of actuator electrodes 50 through 54. In addition, the at least one sensing voltage Us may be tapped at at least two of sensing electrodes 16 through 20, or the at least one electrical output signal 40 may be output with respect to the at least one sensing voltage Us applied between two of sensing electrode 16 through 20. Reference is made to the above-described specific embodiment with respect to further properties of the sensor and/or transducer device schematically shown in FIGS. 2a and 2b.

It is to be noted that the specific embodiment of FIGS. 2a and 2b achieves a complete separation between sensing and actuation by adding electrodes 50 through 54, without this significantly increasing the manufacturing costs or an installation space requirement/an extension of bending structure 10. In particular, the manufacture of actuator electrodes 50 through 54 in addition to sensing electrodes 16 through 20 does not require any additional fabrication steps or any space usable in another way.

In general, an extension al of sensing electrodes 16 through 20 (perpendicular in relation to the direction from first outer electrode 16 to second outer electrode 18) is approximately one-third of extension A of piezoelectric layers 12 and 14 (perpendicular in relation to the direction from first outer electrode 16 to second outer electrode 18). Therefore, actuator electrodes 50 through 54 may be formed having a comparatively large extension a2 (perpendicular in relation to the direction from first outer electrode 16 to second outer electrode 18). Actuator electrodes 50 through 54 may be formed, for example, (almost) twice as large as sensing electrodes 16 through 20. Therefore, on the other hand, the deformation of bending structure 10 resulting from the intrinsic stress gradient may already be counteracted with the aid of at least one comparatively low actuator voltage Ua.

In another specific embodiment, the above-described techniques may also be combined with one another. An additional DC voltage signal may be applied to sensing electrodes 16 through 20, which are preferably located close to or directly on anchored area 10b, so that sensing electrodes 16 through 20 are also used for counteracting the intrinsic stress gradient. This combination has the additional advantage of further smoothing of bending structure 10. In addition, at least one additional sensing voltage may also be tapped at actuator electrodes 50 through 54.

The above-described specific embodiments may have, as a refinement, instead of single bending structure 10, at least two, in particular multiple bending structures 10, which in particular each include the at least one piezoelectric layer 12 and 14. In this case, electronic unit 28 is preferably designed to apply different predefined or established actuator voltages Ua between electrodes 16 through 20 and 50 through 54 of various bending structures 10.

As an additional refinement, each of the above-described sensor and/or transducer devices may also be designed for self-optimization, in that they measure their sound amplification during the operation and set it to an optimized value by adjusting the at least one bending structure 10. This also contributes to improving their functionality and to increasing their sensitivity.

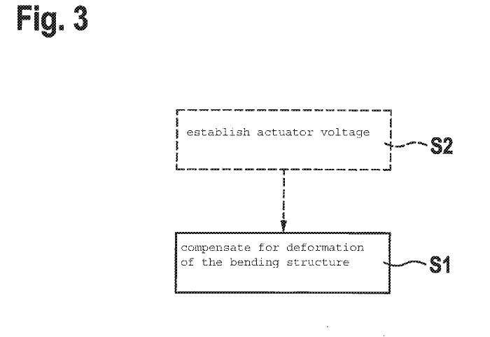

FIG. 3 shows a flow chart to explain a method for operating a sensor and/or transducer device having at least one bending structure, which includes at least one piezoelectric layer.

The method has at least one method step S1, in which a deformation of the bending structure triggered by an intrinsic stress gradient in the bending structure, by which at least one self-supporting area of the bending structure is adjusted in relation to an anchored area of the bending structure under a compression and/or elongation of the at least one piezoelectric layer, is at least partially compensated for. This is carried out by applying at least one predefined or established actuator voltage between two of the electrodes of the bending structure at a time, whose intermediate volume is at least partially filled using the at least one piezoelectric layer. At least two bending structures may possibly also be “bent” into a more optimized form in method step S1. For this purpose, different predefined or established actuator voltages may be applied between the electrodes of various bending structures.

Method step S1 may be carried out in particular to calibrate a sensor and/or transducer device which is designed as a microphone, having the at least one bending structure, which includes the at least one piezoelectric layer. A minimum limiting value of a frequency range which may be amplified (with the aid of the microphone/the particular bending structure) of sound waves is set, by applying the at least one predefined or established actuator voltage between two of the electrodes of the bending structure at a time (whose intermediate volume is at least partially filled using the at least one piezoelectric layer) to at least partially compensate for or increase the deformation of the bending structure triggered by the intrinsic stress gradient in the bending structure (due to which the at least one self-supporting area is adjusted in relation to the anchored area of the bending structure under a compression and/or elongation of the at least one piezoelectric layer).

Method step S1 may be carried out after a fabrication of the sensor and/or transducer device. Alternatively, at least method step S1 may also be regularly repeated to calibrate the sensor and/or transducer device. This makes it possible to reestablish the at least one actuator voltage based on calibration measurements or on surroundings conditions.

For example, windy surroundings may make amplification of certain low frequency sound signals impossible, since this would overload the amplifier. Under these conditions, it is advantageous if the minimum frequency limiting value is automatically increased in such a way that wind noises are already mechanically filtered out on the sensor side. In calm surroundings, the minimum limiting value may be established at the lowest possible value, in contrast, which significantly improves a signal quality. Method step S1 is therefore preferably carried out in such a way that in calm surroundings, a first minimum limiting value of the frequency range of sound waves which may be amplified is set with the aid of at least one predefined or established first actuator voltage, and in windy surroundings, a second limiting value, which is greater compared to the first minimum limiting value, of the frequency range of sound waves which may be amplified is set with the aid of at least one predefined or established second actuator voltage.

In one refinement, prior to method step S1, an optional method step S2 may also be carried out to establish the at least one actuator voltage. For example, at least one initial value for at least one lower limiting value of sound waves which may be amplified with the aid of the at least one bending structure may be measured, and subsequently the at least one actuator voltage may be established in consideration of the at least one measured initial value. Alternatively, other methods may also be applied for directly demonstrating the deformation of the at least one bending structure existing due to the at least one intrinsic stress gradient, in order to establish the at least one actuator voltage. For example, the deformation of the at least one bending structure may be measured with the aid of optical methods (in particular interferometry, for example). In all exemplary embodiments of method step S2 described here, the at least one actuator voltage may be established in consideration of the particular obtained information in such a way that the intrinsic stress gradient in the bending structure (and/or its consequences) is at least partially compensated for.

The at least one actuator voltage established in method step S2 may be stored on a nonerasable memory. If method step S2 is repeated multiple times for a self-calibration during operation of the sensor and/or transducer device, the at least one actuator voltage established in method step S2 may also be stored on a nonerasable memory. During a startup of the sensor and/or transducer device, the memory may be read out automatically and the at least one actuator voltage may subsequently be applied accordingly.

What is claimed is:

1. A sensor and/or transducer device, comprising:
at least one bending structure including at least one piezoelectric layer in each case, using which an intermediate volume between at least two electrodes of the bending structure is at least partially filled in each case, the bending structure having at least one self-supporting area which is adjustable in relation to an anchored area of the bending structure under at least one of a compression and an elongation of the at least one piezoelectric layer; and
an electronic unit designed to apply at least one predefined or established actuator voltage between two of the electrodes at a time of the bending structure, in such a way that a deformation of the bending structure triggered by an intrinsic stress gradient in the bending structure is at least partially compensated for.

2. The sensor and/or transducer device as recited in claim 1, wherein the bending structure includes, as electrodes, at least one first outer electrode, at least one second outer electrode, and at least one intermediate electrode situated between the at least one first outer electrode and the at least one second outer electrode, and, as the at least one piezoelectric layer, a first piezoelectric layer is provided in a first intermediate volume between the at least one first outer electrode and the at least one intermediate electrode and a second piezoelectric layer is provided in a second intermediate volume between the at least one intermediate electrode and the at least one second outer electrode.

3. The sensor and/or transducer device as recited in claim 2, wherein the bending structure only includes, as the electrodes, the first outer electrode, the second outer electrode, and the intermediate electrode situated between the first outer electrode and the second outer electrode, and the electronic unit is designed to output at least one electrical output signal with respect to a sensing voltage applied between the first outer electrode and the intermediate electrode and to apply the predefined or established actuator voltage between the intermediate electrode and the second outer electrode.

4. The sensor and/or transducer device as recited in claim 2, wherein the bending structure includes a first sensing electrode and a first actuator electrode as the at least one first outer electrode, a second sensing electrode and a second actuator electrode as the at least one second outer electrode, and a third sensing electrode, which is located between the first sensing electrode and the second sensing electrode, and a third actuator electrode, which is located between the first actuator electrode and the second actuator electrode, as the at least one intermediate electrode, and the electronic unit is designed to output at least one electrical output signal with respect to at least one sensing voltage applied between two of the sensing electrodes at a time and to apply the at least one predefined or established actuator voltage between two of the actuator electrodes at a time.

5. The sensor and/or transducer device as recited in claim 1, wherein the sensor and/or transducer device has at least two bending structures, which each include the at least one piezoelectric layer, and the electronic unit is designed to apply different predefined or established actuator voltages between the electrodes of the at least two bending structures.

6. A microphone including a sensor and/or transducer device, the sensor and/or transducer including:
at least one bending structure including at least one piezoelectric layer in each case, using which an intermediate volume between at least two electrodes of the bending structure is at least partially filled in each case, the bending structure having at least one self-supporting area which is adjustable in relation to an anchored area of the bending structure under at least one of a compression and an elongation of the at least one piezoelectric layer; and
an electronic unit designed to apply at least one predefined or established actuator voltage between two of the electrodes at a time of the bending structure, in such a way that a deformation of the bending structure triggered by an intrinsic stress gradient in the bending structure is at least partially compensated for.

7. The microphone as recited in claim 6, wherein the electronic unit is designed to establish a minimum limiting value of a frequency range of sound waves which may be amplified with the aid of the microphone, in that the at least one predefined or established actuator voltage is applied between two of the electrodes of the bending structure at a time with the aid of the electronic unit in such a way that the deformation of the bending structure triggered by the intrinsic stress gradient in the bending structure is at least partially compensated for.

8. A method for operating a sensor and/or transducer device having at least one bending structure, which includes at least one piezoelectric layer, the method comprising:
at least partially compensating for a deformation, which is triggered by an intrinsic stress gradient in the bending structure, of the bending structure having at least one self-supporting area, which is adjusted in relation to an anchored area of the bending structure under at least one of a compression and an elongation of the at least one piezoelectric layer, by applying at least one predefined or established actuator voltage between two of the electrodes at a time of the bending structure, whose intermediate volume is at least partially filled using the at least one piezoelectric layer.

9. The method as recited in claim 8, wherein different predefined or established actuator voltages are applied between the electrodes of the bending structures.

10. A method for calibrating a microphone having at least one bending structure, which includes at least one piezoelectric layer, the method comprising:
setting a minimum limiting value of a frequency range of sound waves which may be amplified with the aid of the microphone, in that a deformation, which is triggered by an intrinsic stress gradient in the bending structure, of the bending structure having at least one self-supporting area, which is adjusted in relation to an anchored area of the bending structure under at least one of a compression and an elongation of the at least one piezoelectric layer, is one of at least partially compensated for or increased, by applying at least one predefined or established actuator voltage between two of the electrodes at a time of the bending structure, whose intermediate volume is at least partially filled using the at least one piezoelectric layer.

11. The method as recited in claim 10, wherein in calm surroundings, a first minimum limiting value of the frequency range of sound waves which may be amplified is set with the aid of at least one predefined or established first actuator voltage, and in windy surroundings, a second limiting value of the frequency range of sound waves which may be amplified, which is greater compared to the first minimum limiting value, is set with the aid of at least one predefined or established second actuator voltage.
